(19) United States
(12) Patent Application Publication
(10) Pub. No.: US 2015/0228761 A1
(43) Pub. Date: Aug. 13, 2015

(54) DIAMOND SHAPED EPITAXY

(71) Applicant: INTERNATIONAL BUSINESS MACHINES CORPORATION, Armonk, NY (US)

(72) Inventors: Kangguo Cheng, Schenectady, NY (US); Ali Khakifirooz, Los Altos, CA (US); Dominic J. Schepis, Wappingers Falls, NY (US); Raghavasimhan Sreenivasan, Schenectady, NY (US); Alexander Reznicek, Troy, NY (US)

(73) Assignee: INTERNATIONAL BUSINESS MACHINES CORPORATION, Armonk, NY (US)

(21) Appl. No.: 14/174,920

(22) Filed: Feb. 7, 2014

(51) Int. Cl. H01L 29/66; H01L 29/78; H01L 21/8234

(52) U.S. Cl. CPC H01L 29/66795; H01L 21/823431; H01L 29/785

(57) ABSTRACT

In a first embodiment of the present invention, a semiconductor device manufacturing process includes forming a plurality of fins on a semiconductor substrate, forming diamond shaped epitaxy on fin sidewalls, merging the diamond shaped epitaxy, and removing the merged epitaxy. In another embodiment of the present invention, a semiconductor device includes a semiconductor substrate including a plurality of fins formed thereupon and unmerged diamond shaped epitaxy formed upon the sidewalls of each fin. The unmerged diamond shaped epitaxy is formed independent from neighboring fin geometry deficiencies. In yet another embodiment, the semiconductor device is included in a design structure embodied in a machine readable storage medium for designing, manufacturing, or testing an integrated circuit.

### FIELD

Embodiments of invention generally relate to semiconductor devices, design structures for designing a semiconductor device, and semiconductor device fabrication methods. More particularly, embodiments relate to semiconductor structures (e.g. FinFET structures, etc.) with diamond epitaxy thereupon.

### SUMMARY

Embodiments of invention generally relate to semiconductor devices, and more particularly to design structures, semiconductor devices, and fabrication of a semiconductor devices with dual epitaxy regions.

In a first embodiment of the present invention, a semiconductor device fabrication process includes forming a plurality of fins on a semiconductor substrate, forming diamond shaped epitaxy on fin sidewalls, merging the diamond shaped epitaxy, and removing the merged epitaxy. In other words, in this embodiment diamond shaped epitaxy is formed by merging the epitaxy and etching the epitaxy to form a diamond shape.

In another embodiment of the present invention, a semiconductor device includes a semiconductor substrate including a plurality of fins formed thereupon, and unmerged diamond shaped epitaxy formed upon the sidewalls of each fin. The unmerged diamond shaped epitaxy is formed independent from neighboring fin geometry deficiencies.

In yet another embodiment, the semiconductor device is included in a design structure embodied in a machine readable storage medium for designing, manufacturing, or testing an integrated circuit.

These and other embodiments, features, aspects, and advantages will become better understood with reference to the following description, appended claims, and accompanying drawings.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1A and FIG. 1B depict an isometric view of a semiconductor structure at an intermediate stage of semiconductor device fabrication, in accordance with various embodiments of the present invention.

FIG. 2A and FIG. 2B depict a cross section view of a semiconductor structure at an intermediate stage of semiconductor device fabrication, in accordance with various embodiments of the present invention.

FIG. 3A and FIG. 3B depict an isometric view of a semiconductor structure at an intermediate stage of semiconductor device fabrication, in accordance with various embodiments of the present invention.

FIG. 4A and FIG. 4B depict a cross section view of a semiconductor structure at an intermediate stage of semiconductor device fabrication, in accordance with various embodiments of the present invention.

FIG. 5A and FIG. 5B depict a cross section view of a semiconductor structure at an intermediate stage of semiconductor device fabrication, in accordance with various embodiments of the present invention.

FIG. 6A and FIG. 6B depict a cross section view of a semiconductor structure at an intermediate stage of semiconductor device fabrication, in accordance with various embodiments of the present invention.

FIG. 7A and FIG. 7B depict a cross section view of a semiconductor structure at an intermediate stage of semiconductor device fabrication, in accordance with various embodiments of the present invention.

FIG. 8 depicts an exemplary process flow, in accordance with various embodiments of the present invention.

FIG. 9 depicts a flow diagram of a design process used in semiconductor design, manufacture, and/or test, in accordance with various embodiments of the present invention.

The drawings are not necessarily to scale. The drawings are merely schematic representations, not intended to portray specific parameters of the invention. The drawings are intended to depict only exemplary embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. These exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

Embodiments of invention generally relate to semiconductor devices, and more particularly to the formation of, and structures utilizing FinFETs. A FinFET device may include a plurality of fins formed in a wafer and a gate covering a portion of the fins. The portion of the fins covered by the gate may serve as a channel region of the device. Portions of the fins may also extend out from under the gate and may serve as source and drain regions of the device.

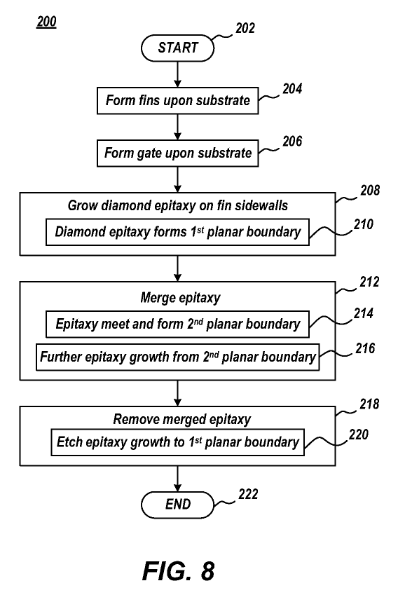

For the purposes of this document, it is noted that specific elements are denoted by a numeral and a subscript (e.g. FIG. 7B, 10a, 14b, etc.). When elements are referred to generically, merely the numeral is used (e.g. FIG. 7, 10, 14, etc.). Referring now to the figures, exemplary process steps of forming a structure 10 in accordance with embodiments of the present invention are shown, and will now be described in greater detail below. It should be noted that some of the figures depict a cross section view of structure 10. Furthermore, it should be noted that while this description may refer to some components of the structure 10 in the singular tense, more than one component may be depicted throughout the figures and like components are labeled with like numerals. The specific number of components depicted in the figures and the cross section orientation was chosen for illustrative purposes only.

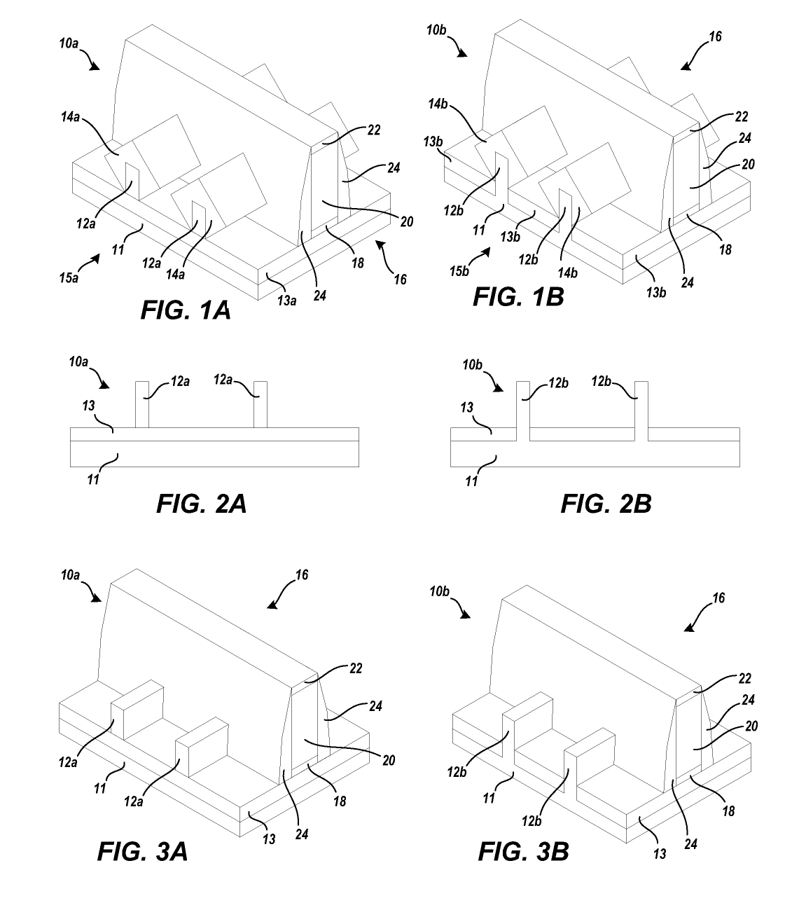

FIG. 1A and FIG. 1B depict an isometric view of a semiconductor structures 10a and 10b, respectively, at an intermediate stage of semiconductor device fabrication, in accordance with various embodiments of the present invention. Semiconductor structure 10a includes a layered substrate 15a and semiconductor structure 10b includes a bulk substrate 15b. Referring to both FIG. 1A and FIG. 1B, semiconductor structure 10 includes a substrate 15 having a plurality of fins 12 formed thereupon. A gate stack 16 is formed upon substrate 15 generally perpendicular to fins 12. Epitaxy 14 is formed upon the sidewalls of fins 12, according to various embodiments of the present invention further described herein.

Semiconductor substrate 15 a layered semiconductor 15a such as Si/SiGe, a silicon-on-insulator (SOI), or a SiGe-on-insulator (SGOI). Bulk semiconductor substrate 15b materials may include undoped Si, n-doped Si, p-doped Si, single crystal Si, polycrystalline Si, amorphous Si, Ge, SiGe, SiC, SiGeC, GaAs, InAs, InP, etc. A plurality of fins 12 may be etched from the substrate 15.

When an layered substrate 15a is utilized, it may include a base substrate 11, a buried dielectric layer 13a formed on top of the base substrate, and a SOI layer formed on top of the buried dielectric layer. The buried dielectric layer 13a may isolate the SOI layer from the base substrate. The plurality of fins 12a may be etched from the SOI layer. The base substrate 11 may be made from any of several known semiconductor materials such as, for example, silicon, germanium, silicon-germanium alloy, silicon carbide, silicon-germanium carbide alloy, or other similar semiconductor materials. Non-limiting examples of compound semiconductor materials include gallium arsenide, indium arsenide, and indium phosphide. Typically the base substrate 11 may be about, but is not limited to, several hundred microns thick. For example, the base substrate may have a thickness ranging from 0.5 mm to about 1.5 mm.

The buried dielectric layer 13a may include any of several dielectric materials, for example, oxides, nitrides and oxynitrides of silicon. The buried dielectric layer 13a may also include oxides, nitrides and oxynitrides of elements other than silicon. In addition, the buried dielectric layer 13a may include crystalline or non-crystalline dielectric material. Moreover, the buried dielectric layer 13a may be formed using any of several known methods, for example, thermal or plasma oxidation or nitridation methods, chemical vapor deposition methods, and physical vapor deposition methods. The buried dielectric layer 13a may have a thickness ranging from about 5 nm to about 200 nm. In one embodiment, the buried dielectric layer may have a thickness ranging from about 150 nm to about 180 nm.

The SOI layer may include any of the several semiconductor materials included in the base substrate. In general, the base substrate and the SOI layer may include either identical or different semiconducting materials with respect to chemical composition, dopant concentration and crystallographic orientation. The base substrate 11a and the SOI layer include semiconducting materials that include at least different crystallographic orientations. Typically, the SOI layer may include a thickness ranging from about 5 nm to about 100 nm. In one embodiment, the SOI layer may have a thickness ranging from about 25 nm to about 30 nm. Methods for forming the SOI layer are well known in the art. Non-limiting examples include SIMOX (Separation by Implantation of Oxygen), wafer bonding, and ELTRAN® (Epitaxial Layer TRANsfer). It may be understood by a person having ordinary skill in the art that the plurality of fins 12a may be etched from the SOI layer. Because the plurality of fins may be etched from the SOI layer, they too may include any of the characteristics listed above for the SOI layer.

When a bulk substrate 15b is utilized, the base substrate 11 may be etched to form fins 12b. Dielectric portions 13b may then be formed between fins 12b and may include any of several dielectric materials, for example, oxides, nitrides and oxynitrides of silicon. The dielectric portions 13b may also include oxides, nitrides and oxynitrides of elements other than silicon. In addition, the dielectric portions 13b may include crystalline or non-crystalline dielectric material. Moreover, the dielectric portions 13b may be formed using any of several known methods, for example, chemical vapor deposition methods, and physical vapor deposition methods. The dielectric portions 13b may have a thickness ranging from about 5 nm to about 200 nm. In one embodiment, the dielectric portions 13b may have a thickness ranging from about 5 nm to about 50 nm, with 10 nm to 25 nm preferred. In certain embodiments, dielectric portions 13b may be etched or recessed following their formation.

Semiconductor structure 10 may also include a gate stack 16. Gate stack 16 may include a gate dielectric 18, a gate 20, a gate cap 22, and spacers 24. Generally, gate stack 16 may be formed by using widely known techniques. For example, gate stack 20 may be formed by first providing a gate dielectric 18 layer atop structure 10 (i.e. upon substrate 15 and fins 12) utilizing a conventional deposition process including, for example, chemical vapor deposition, plasma enhanced chemical vapor deposition or chemical solution deposition. A layer gate 20 material may be formed upon gate dielectric 18, and a gate cap 22 formed upon gate 20. The stack may then patterned by lithography and etched to form a gate stack 16. In certain embodiments, spacers 24 may be formed on the sides of gate stack 16. Generally, gate stack 16 may be formed by other known processes without deviating from the spirit of those embodiments herein claimed.

Semiconductor structure 10 may also include diamond epitaxy 14, the formation of which is further described herein. Generally, expitaxial growth, grown, deposition, formation, etc. means the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gasses are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. For example, an epitaxial semiconductor material deposited on a <100> crystal surface will take on a <100> orientation. In some embodiments, epitaxial growth and/or deposition processes are selective to forming on semiconductor surface, and do not deposit material on dielectric surfaces, such as silicon dioxide or silicon nitride surfaces.

Examples of various epitaxial growth process apparatuses that are suitable for use in forming epitaxial semiconductor material of the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition process for forming the carbon doped epitaxial semiconductor material typically ranges from 550° C. to 900° C. Although higher temperature typically results in faster deposition, the faster deposition may result in crystal defects, film cracking, etc.

For clarity, semiconductor structure 10 may be fabricated by a “gate first” process or a “gate last” process. In a gate first process, metal layers over first structure areas (e.g. NMOS areas, etc.) and second structure areas (e.g. PMOS areas, etc.) are formed and patterned to form gate structures followed by typical CMOS processing such as forming of the source and drain, forming spacers and depositing of the interlevel dielectric. In a gate last process, a dummy gate structure is formed followed by typical CMOS processing including formation of the source and drain, formation of spacers and deposition of the interlevel dielectric. Thereafter, the dummy gate structure is removed followed by deposition of a replacement gate structure.

FIG. 2A and FIG. 2B depict a cross section view of a semiconductor structure 10 at an intermediate stage of semiconductor device fabrication, in accordance with various embodiments of the present invention. At this stage of fabrication, fins 12 are formed upon semiconductor structure 10. As shown in FIG. 2A, the layered substrate 15a may include the base substrate 11a and the buried dielectric layer 13a formed on top of the base substrate. A SOI layer (not shown) is formed on top of the buried dielectric layer 13a. The buried dielectric layer 13a may isolate the SOI layer from the base substrate. The plurality of fins 12a may be etched from the SOI layer. As shown in FIG. 2B, the bulk substrate 15b may include the base substrate 11b. Fins 12b may be etched from base substrate 11b. Dielectric portions 13b may then be formed between fins 12b. In certain embodiments, dielectric portions 13b may be etched or recessed following their formation. Generally, fins 12 may be formed upon a semiconductor structure 10 by other known processes or techniques without deviating from the spirit of those embodiments herein claimed.

FIG. 3A and FIG. 3B depict an isometric view of a semiconductor structure 10 at an intermediate stage of semiconductor device fabrication, in accordance with various embodiments of the present invention. At this stage of fabrication, gate stack 20 is formed upon semiconductor structure 10. In certain embodiments, a gate dielectric 18 layer is formed atop semiconductor structure 10 (i.e. upon substrate 15 and fins 12) generally orthogonal to fins 12 utilizing a conventional deposition process including, for example, chemical vapor deposition, plasma enhanced chemical vapor deposition or chemical solution deposition. A layer of gate 20 material may be formed upon gate dielectric 18, and a gate cap 22 formed upon gate 20. The layers may then patterned by lithography and etched to form a gate stack 16. In certain embodiments, spacers 24 may be formed on the sides of gate stack 16. Generally, gate stack 16 may be formed by other known processes without deviating from the spirit of those embodiments herein claimed.

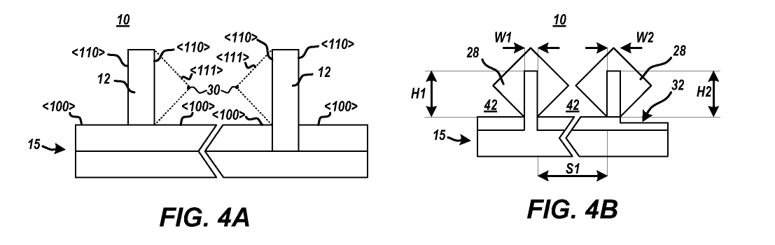

FIG. 4A and FIG. 4B depict a cross section view of a semiconductor structure 10 at an intermediate stage of semiconductor device fabrication, in accordance with various embodiments of the present invention. At this stage of fabrication, pre-merge diamond epitaxy 28 is formed upon semiconductor structure 10. More specifically, pre-merge diamond epitaxy 28 is epitaxially grown upon fins 12. As shown in FIG. 4A, substrate 15 has a <100> orientation and fin 12 sidewalls have a <110> orientation. Epitaxy is grown off the fin 12 sidewalls and a diamond structure is formed around fins 12. Upon growing from <110> orientation, fin 12 sidewalls, the diamond structure will have outer <111> plane. As shown in FIG. 4B, pre-merge diamond epitaxy 28 are grown from the sidewalls of fins 12 and may result in voids 42 being formed between neighboring fins 12. Generally, voids 42 are the absence of epitaxial growth. A non limiting list of exemplary expitaxial materials are: silicon germanium alloy (SiGe), Silicon (Si), in-situ boron doped SiGe or Si, in situ phosphorus or arsenic doped Si or SiGe, with doping levels ranging from 1e19 to 1.5e21, with 4-9e20 dopant levels preferred.

Generally, epitaxy growth is quickest from <100> planes and is slowest from <111> planes. When epitaxy growth from fin 12 sidewalls is complete, <111> bound diamond shaped structures form resulting pre-merge diamond shaped epitaxy 28, as is shown in FIG. 4B. At this time, epitaxial growth from the <111> plane slows. However, neighboring pre-merge diamond shaped epitaxy 28 may merge. For example, tips 30 of neighboring pre-merge diamond shaped epitaxy 28 may meet. When pre-merge diamond shaped epitaxy 28 structures merge, a <100> plane is formed there between. The epitaxy from the <100> plane grows quickly in a generally vertical direction.

There are many variables that affect whether particular diamond shaped epitaxy structures merge, while other diamond shaped epitaxy structures do not. One of these variables are fin 12 geometry. If the geometry of fins 12 within a neighboring fin 12 pair differ, it is difficult to control diamond shaped epitaxy merging. Thus merging of diamond shaped epitaxy is dependent upon the fin 12 geometry of the neighboring fin 12 geometry. For example, fin height (H1, H2, etc.) similarity, fin 12 width (W1, W2, etc.) similarity, fin shape, etc. of neighboring fins 12 will affect epitaxy merging to that associated with a neighboring fin 12. Further, fin 12 pair spacing (e.g. Si, etc.) will affect merging as will the presence of a substrate gouge(s) 32. Even further, fin 12 erosion and affects from fin 12 clean processing will also affect merging. Therefore, it is desired to form unmerged diamond epitaxy independent from neighboring fin geometry deficiencies. Further, because utilizing merged epitaxy could lead to shorts and/or other defects, it may be advantageous to utilize diamond shaped unmerged epitaxy, for example at 14 nm nodes and beyond, to reduce the amount of epitaxial growth on isolated fins, on border fins, or in ever increasing smaller device areas.

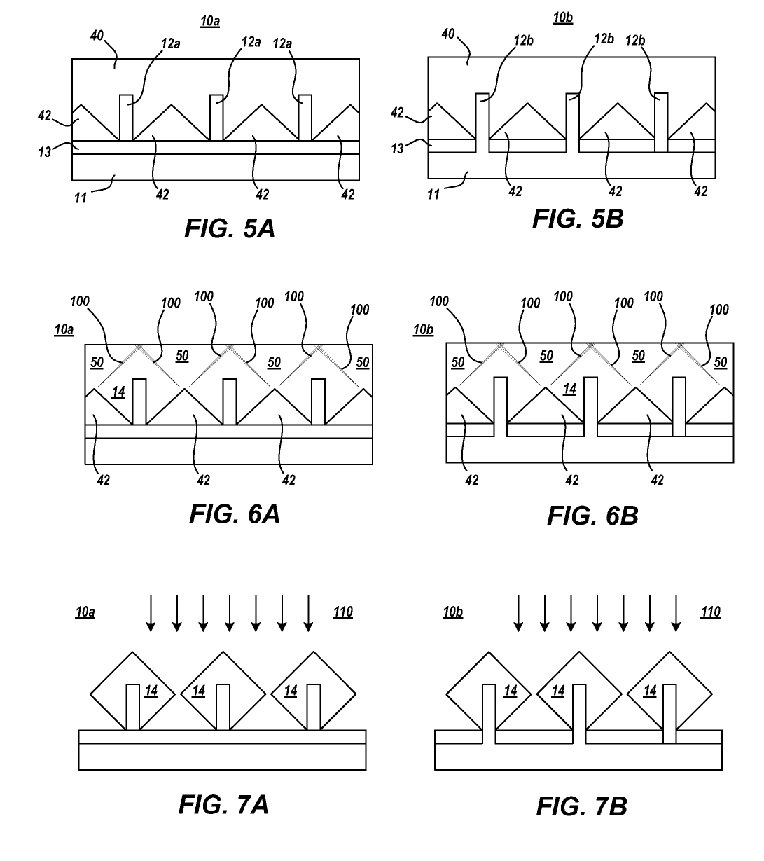

FIG. 5A and FIG. 5B depict a cross section view of a semiconductor structure 10 at an intermediate stage of semiconductor device fabrication, in accordance with various embodiments of the present invention. At this stage of fabrication, pre-merge diamond shaped epitaxy 28 has merged to form epitaxial overgrowth 40 upon semiconductor structure 10. Generally, overgrowth 40 is formed from continued epitaxial growth subsequent to epitaxy merging. In certain embodiments overgrowth is generally block epitaxy formed generally above fins 12. In certain embodiments, overgrowth 40 is formed by generally vertical epitaxial growth from the <100> plane created when neighboring tips 30 of pre-merge diamond shaped epitaxy 28 meet. In certain embodiments, excessive overgrowth is avoided. In certain embodiments, overgrowth 40 is grown to 20 nm above the upper surfaces of fins 12.

FIG. 6A and FIG. 6B depict a cross section view of a semiconductor structure 10 at a similar stage of semiconductor device fabrication relative to that shown in FIG. 5A and in FIG. 5B. During overgrowth 40 formation, crystal defects 100 form. Crystal defects 100 generally result from the misalignment of lattice planes of neighboring diamond shaped epitaxial structures as well as the different epitaxial growth properties involved in pre-merge diamond shaped epitaxy 28 and overgrowth 40 formation (e.g. epitaxial growth from fin 12 sidewall <110> plane, diamond shaped epitaxy 14 formation with <111> plane border, overgrowth via continued epitaxial growth from the created <100> plane, etc.). In certain embodiments, crystal defects 100 are the upper boundary of <111> plane border created when pre-merge diamond shaped epitaxy 28 are formed. In certain embodiments, overgrowth 40 may include portion 50 generally above and between crystal defects 100. Portions 50 are generally the vertical epitaxial material growth from the <100> plane created when tips 30 of neighboring pre-merge diamond shaped epitaxy 28 merge. Crystal defects 100 generally form the lower boundary to portions 50. As such, crystal defects 100 generally form a border between pre-merge diamond shaped epitaxy 28 and portions 50.

FIG. 7A and FIG. 7B depict a cross section view of a semiconductor structure 10 at an intermediate stage of semiconductor device fabrication, in accordance with various embodiments of the present invention. At this stage of fabrication, semiconductor structure 10 undergoes an etch process 110 to remove portions 50 resulting in unmerged diamond shaped epitaxy 14. Etch process 110 is generally a self-limiting wet etch using an etchant (e.g. hydrochloric acid, tetramethylammonium hydroxide, Ammonia, etc.) to etch away portions 50 selective to crystal defects 100. Since portions 50 are generally <100> epitaxial growth, portions 50 are etched more rapidly than, for example, <111> epitaxy. The etchant of etch process 110 slows once the enchant hits the defect free portion of <111> plane of the diamond shaped epitaxy. Upon when portions 50 are effectively removed, semiconductor structure 10 is removed from the etchant and diamond shaped epitaxy 14 remains. Etch process 110 thereby forms unmerged diamond shaped epitaxy 14 individually on each fin 12 independent from relative neighboring fin 12 pair geometry deficiencies.

FIG. 8 depicts an exemplary process flow 200 for manufacturing a semiconductor device, in accordance with various embodiments of the present invention. Process 200 begins at block 202 and continues by forming fins 12 upon a substrate 15 (block 204). In certain embodiments, a gate 20 (gate stack 16, etc.) is formed upon the substrate (block 206). The gate may be formed generally orthogonal to fins 12. Pre-merge diamond shaped epitaxy 28 is grown on fin 12 side walls (block 208). For example, epitaxy is grown off the <110> plane fin 12 sidewalls. The outer boundary of pre-merge diamond shaped epitaxy 28 forms a <111> planar boundary (block 210).

Process 200 continues by merging neighboring diamond shaped epitaxy 28 (block 212). For example, tips 30 of neighboring diamond shaped epitaxy 28 may meet and form a <100> planar boundary (block 214) whereby epitaxy grows vertically there from (block 216). For example, further epitaxial growth from the <100> planar boundary results in overgrowth 40.

Process 200 continues by removing the merged epitaxy (block 218). For example, a etchant is used to remove portions 50 selective to the <111> planar boundary to form diamond shaped epitaxy 14 (block 220) individually on each fin 12 independent from relative neighboring fin 12 pair geometry deficiencies. Process 200 ends at block 222.

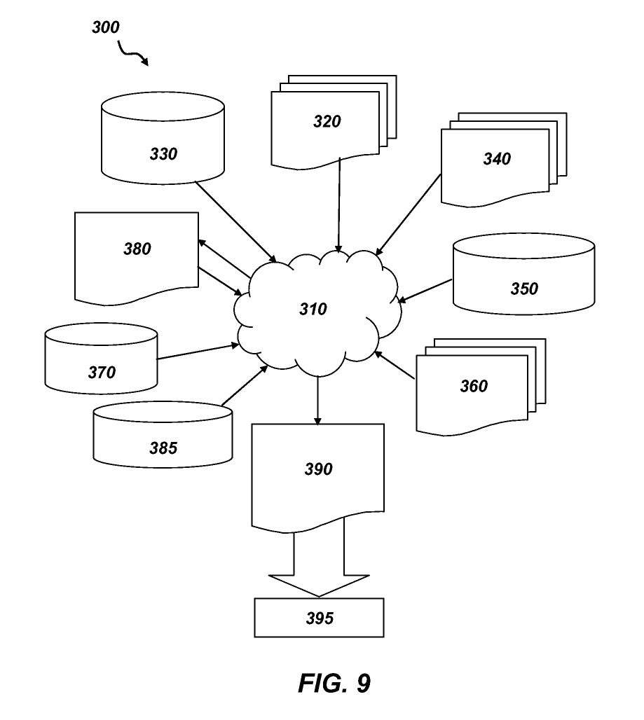

Referring now to FIG. 9, a block diagram of an exemplary design flow 300 used for example, in semiconductor integrated circuit (IC) logic design, simulation, test, layout, and/or manufacture is shown. Design flow 300 includes processes, machines and/or mechanisms for processing design structures or devices to generate logically or otherwise functionally equivalent representations of the structures and/or devices described above and shown in FIGS. 1-7.

The design structures processed and/or generated by design flow 300 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 300 may vary depending on the type of representation being designed. For example, a design flow 300 for building an application specific IC (ASIC) may differ from a design flow 300 for designing a standard component or from a design flow 300 for instantiating the design into a programmable array, for example a programmable gate array (PGA) or a field programmable gate array (FPGA) offered by Altera® Inc. or Xilinx® Inc.

FIG. 9 illustrates multiple such design structures including an input design structure 320 that is preferably processed by a design process 310. Design structure 320 may be a logical simulation design structure generated and processed by design process 310 to produce a logically equivalent functional representation of a hardware device. Design structure 320 may also or alternatively comprise data and/or program instructions that when processed by design process 310, generate a functional representation of the physical structure of a hardware device. Whether representing functional and/or structural design features, design structure 320 may be generated using electronic computer-aided design (ECAD) such as implemented by a core developer/designer.

When encoded on a machine-readable data transmission, gate array, or storage medium, design structure 320 may be accessed and processed by one or more hardware and/or software modules within design process 310 to simulate or otherwise functionally represent an electronic component, circuit, electronic or logic module, apparatus, device, structure, or system such as those shown in FIGS. 1-7. As such, design structure 320 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 310 preferably employs and incorporates hardware and/or software modules for synthesizing, translating, or otherwise processing a design/simulation functional equivalent of the components, circuits, devices, or structures shown FIGS. 1-7 to generate a Netlist 380 which may contain design structures such as design structure 320. Netlist 380 may comprise, for example, compiled or otherwise processed data structures representing a list of wires, discrete components, logic gates, control circuits, I/O devices, models, etc. that describes the connections to other elements and circuits in an integrated circuit design. Netlist 380 may be synthesized using an iterative process in which netlist 380 is resynthesized one or more times depending on design specifications and parameters for the device. As with other design structure types described herein, netlist 380 may be recorded on a machine-readable data storage medium or programmed into a programmable gate array. The storage medium may be a non-volatile storage medium such as a magnetic or optical disk drive, a programmable gate array, a compact flash, or other flash memory. Additionally, or in the alternative, the storage medium may be a system or cache memory, buffer space, or electrically or optically conductive devices in which data packets may be intermediately stored.

Design process 310 may include hardware and software modules for processing a variety of input data structure types including Netlist 380. Such data structure types may reside, for example, within library elements 330 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 340, characterization data 350, verification data 360, design rules 370, and test data files 385 which may include input test patterns, output test results, and other testing information. Design process 310 may further include, for example, standard mechanical design processes such as stress analysis, thermal analysis, mechanical event simulation, process simulation for operations such as casting, molding, and die press forming, etc.

One of ordinary skill in the art of mechanical design can appreciate the extent of possible mechanical design tools and applications used in design process 310 without deviating from the scope and spirit of the invention claimed herein. Design process 310 may also include modules for performing standard circuit design processes such as timing analysis, verification, design rule checking, place and route operations, etc.

Design process 310 employs and incorporates logic and physical design tools such as HDL compilers and simulation model build tools to process design structure 320 together with some or all of the depicted supporting data structures along with any additional mechanical design or data (if applicable), to generate a second design structure 390. Design structure 390 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures).

Similar to design structure 320, design structure 390 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-7. In one embodiment, design structure 390 may comprise a compiled, executable HDL simulation model that functionally simulates the devices shown in FIGS. 1-7.

Design structure 390 may also employ a data format used for the exchange of layout data of integrated circuits and/or symbolic data format (e.g. information stored in a GDSII (GDS2), GL1, OASIS, map files, or any other suitable format for storing such design data structures). Design structure 390 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-7. Design structure 390 may then proceed to a stage 395 where, for example, design structure 390: proceeds to tape-out, is released to manufacturing, is released to a mask house, is sent to another design house, is sent back to the customer, etc.

The accompanying figures and this description depicted and described embodiments of the present invention, and features and components thereof. Those skilled in the art will appreciate that any particular nomenclature used in this description was merely for convenience, and thus the invention should not be limited by the specific process identified and/or implied by such nomenclature. Therefore, it is desired that the embodiments described herein be considered in all respects as illustrative, not restrictive, and that reference be made to the appended claims for determining the scope of the invention.

References herein to terms such as “vertical”, “horizontal”, etc. are made by way of example, and not by way of limitation, to establish a frame of reference. The term “horizontal” as used herein is defined as a plane parallel to the conventional plane or surface of the substrate, regardless of the actual spatial orientation of the semiconductor substrate. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

The invention claimed is:

1. A semiconductor device fabrication process comprising:
forming a plurality of fins on a semiconductor substrate;
forming diamond shaped epitaxy on fin sidewalls;
merging the diamond shaped epitaxy, and;
selectively removing the merged epitaxy.

2. The process of claim 1 wherein forming diamond shaped epitaxy on fin sidewalls further comprises:
forming a first planar boundary, the first planar boundary generally diamond shaped shaped.

3. The process of claim 1 wherein merging the diamond shaped epitaxy further comprises:
allowing the diamond shaped epitaxy of neighboring fins to meet to form a second planar boundary.

4. The process of claim 3 wherein merging the diamond shaped epitaxy further comprises:
overgrowing the merged epitaxy grown from the second planar boundary.

5. The process of claim 2 wherein removing the merged epitaxy further comprises:
etching the merged epitaxy selective to the first planar boundary.

6. The process of claim 2 wherein the first planar boundary is a <111> epitaxial planar boundary.

7. The process of claim 4 wherein the second planar boundary is a <100> epitaxial planar boundary.

8. The process of claim 1 wherein forming diamond shaped epitaxy on fin sidewalls further comprises:
forming diamond shaped epitaxy on a <110> planar boundary of the fin sidewalls.

9. The process of claim 1 wherein the semiconductor substrate is a layered substrate.

10. The process of claim 1 wherein the semiconductor substrate is a bulk substrate.

11. The process of claim 1 wherein forming diamond shaped epitaxy on fin sidewalls further comprises:
forming epitaxial growth voids between neighboring fins, the void perimeter generally formed by respective diamond shaped epitaxy first planar boundaries and the upper surface of the semiconductor substrate.

12. The process of claim 2 wherein the first planar boundary is a plane of crystal defects within the epitaxial growth.

13. The process of claim 1 further comprising:
forming a gate upon the substrate generally orthogonal to the plurality of fins.

14. The process of claim 1 wherein removing the merged epitaxy forms unmerged diamond shaped epitaxy upon each of the plurality of fins, wherein the unmerged diamond shaped epitaxy is formed independent of neighboring fin geometry deficiencies.

15. A semiconductor device comprising:
a semiconductor substrate comprising a plurality of fins formed thereupon, and;
unmerged diamond shaped epitaxy formed upon the sidewalls of each fin, wherein the unmerged diamond shaped epitaxy is formed independent from neighboring fin geometry deficiencies.

16. The semiconductor device of claim 15, wherein the unmerged diamond shaped epitaxy has a <111> epitaxial planar border.

17. The semiconductor device of claim 16 wherein the unmerged diamond shaped epitaxy is formed by etching merged epitaxy portions selective to the <111> epitaxial planar border.

18. A design structure embodied in a machine readable storage medium for designing, manufacturing, or testing an integrated circuit, the design structure comprising:
a semiconductor substrate comprising a plurality of fins formed thereupon, and;
unmerged diamond shaped epitaxy formed upon the sidewalls of each fin, wherein the unmerged diamond shaped epitaxy is formed independent from neighboring fin geometry deficiencies.

19. The design structure of claim 18, wherein the unmerged diamond shaped epitaxy has a <111> epitaxial planar border.

20. The design structure of claim 19, wherein the unmerged diamond shaped epitaxy is formed by etching merged epitaxy portions selective to the <111> epitaxial planar border
